(19) United States
(12) Patent Application Publication
(10) Pub. No.: US 2026/0052846 A1
(43) Pub. Date: Feb. 19, 2026

(54) REFLECTION CONTROL PATTERN, DISPLAY DEVICE HAVING THE SAME AND ELECTRONIC DEVICE INCLUDING DISPLAY DEVICE

(71) Applicant: Samsung Display Co., LTD., Yongin-si (KR)

(72) Inventor: YOONHO KANG, Yongin-si (KR)

(21) Appl. No.: 19/078,421

(22) Filed: Mar. 13, 2025

(30) Foreign Application Priority Data
Aug. 19, 2024 (KR) 10-2024-0110548

(51) Int. Cl. H10K 59/122; H10K 59/80

(52) U.S. Cl. CPC H10K 59/122; H10K 59/8792

(57) ABSTRACT

A display device of an electronic device includes a display area including a light emitting area including a light emitting element and a color filter, and a non-light emitting area which is adjacent to the light emitting area, an encapsulation layer which is on the light emitting element, a bank structure which is in the non-light emitting area, on the encapsulation layer, a groove which is in the light emitting area and defined by the color filter together with the bank structure; and a reflection control pattern in the groove.

This application claims priority to Korean Patent Application No. 10-2024-0110548 filed on Aug. 19, 2024, and all the benefits accruing therefrom under 35 U.S.C. § 119, the entire disclosure of which is incorporated by reference herein.

### BACKGROUND

### 1. Field

Embodiments relate to a display device. More specifically, embodiments relate to a display device which provides visual information and an electronic device including the display device.

### 2. Description of the Related Art

Electrodes, lines, or the like of a display panel included in a display device may reflect various types of light. When light is generated from a light emitting element of the display device, some of the light generated from the light emitting element may be reflected from the electrodes, the lines, or the like of the display panel. In addition, when an external light source exists, external light which enters inside of the display device from outside of the display device may be reflected from the electrodes, the lines, or the like of the display panel.

### SUMMARY

When internal light from a light emitting element or external light from outside a display device is reflected by components of the display device, such as electrodes, conductive line, signal lines, etc. of a display panel in the display device, the reflected light may be visually recognized from the outside of the display device and may affect the display quality of the display device and/or the electronic device.

Embodiments provide a display device with improved display quality.

Embodiments provide an electronic device including the display device.

A display device according to an embodiment of the present disclosure includes a substrate including a light emitting area and a non-light emitting area, a light emitting element arranged in the light emitting area on the substrate, an encapsulation layer arranged on the light emitting element, a color filter arranged in the light emitting area on the encapsulation layer, a bank structure arranged in the non-light emitting area on the encapsulation layer, a groove defined between the color filter and the bank structure, and a reflection control pattern arranged in the groove.

In an embodiment, the reflection control pattern may have a color which corrects a color of reflected light in the light emitting area.

In an embodiment, the bank structure may include a first bank having a first width in a width direction, and a second bank arranged on the first bank and having a second width less than or equal to the first width in the width direction.

In an embodiment, a first thickness of the first bank in a thickness direction may be less than a second thickness of the color filter in the thickness direction.

In an embodiment, the groove may be defined between the color filter and the second bank.

In an embodiment, the first bank and the second bank may include different materials.

In an embodiment, the first bank may include a light blocking material.

In an embodiment, the second bank may include a liquid-repellent material.

In an embodiment, the light emitting element may include a first light emitting element which emits first light, a second light emitting element which emits second light, and a third light emitting element which emits a third light, and the color filter may include a first color filter overlapping the first light emitting element in a plan view, a second color filter overlapping the second light emitting element in the plan view, and a third color filter overlapping the third light emitting element in the plan view.

In an embodiment, a first groove may be defined between the first color filter and the second bank, and a second groove may be defined between the second color filter and the second bank.

In an embodiment, the reflection control pattern may include a first reflection control pattern arranged in the first groove, and a second reflection control pattern arranged in the second groove.

In an embodiment, the first reflection control pattern may have a color which corrects a color of the first light, and the second reflection control pattern may have a color which corrects a color of the second light.

In an embodiment, the first color filter may selectively transmit the first light, the second color filter may selectively transmit the second light, and the third color filter may selectively transmit the third light.

In an embodiment, the first light may be light of a red wavelength band, the second light may be light of a green wavelength band, and the third light may be light of a blue wavelength band.

In an embodiment, the third color filter and the first bank may include a same material.

In an embodiment, the third color filter and the first bank may be formed through a same process.

In an embodiment, the first color filter and the second bank may include a same material.

In an embodiment, the reflection control pattern may be formed through an inkjet process.

In an embodiment, the reflection control pattern may have a primary color or a secondary color.

In an embodiment, the color filter may be formed through an inkjet process.

An electronic device according to an embodiment of the present disclosure includes a display device, and a power module which supplies power to the display device. The display device may include a substrate including a light emitting area and a non-light emitting area, a light emitting element arranged in the light emitting area on the substrate, an encapsulation layer arranged on the light emitting element, a color filter arranged in the light emitting area on the encapsulation layer, a bank structure arranged in the non-light emitting area on the encapsulation layer, a groove defined between the color filter and the bank structure, and a reflection control pattern arranged in the groove.

In a display device according to embodiments of the present disclosure, the display device may include a bank structure having a multilayer structure and a reflection control pattern arranged adjacent to a color filter. The bank structure may include a first bank and a second bank arranged on the first bank, and the reflection control pattern may be arranged in a groove defined between the color filter and the second bank. The second bank may reduce reflection of the first bank, and the reflection control pattern may correct color quality of reflected light. Accordingly, reflection of external light of the display device may be reduced, and color quality of reflection of the display device may be improved.

### BRIEF DESCRIPTION OF THE DRAWINGS

FIG. 1 is a perspective view illustrating a display device according to an embodiment of the present disclosure.

FIG. 2 is an enlarged cross-sectional view illustrating a portion of a display area of the display device of FIG. 1.

FIGS. 3, 4, 5, and 6 are enlarged cross-sectional views illustrating processes in a method of manufacturing (or providing) a display device according to an embodiment of the present disclosure.

FIG. 7 is an enlarged cross-sectional view illustrating a display device according to an embodiment of the present disclosure.

FIG. 8 is an enlarged cross-sectional view illustrating a display device according to an embodiment of the present disclosure.

FIGS. 9, 10, 11, and 12 are enlarged cross-sectional views illustrating processes in a method of manufacturing (or providing) a display device according to an embodiment of the present disclosure.

FIG. 13 is an enlarged cross-sectional view illustrating a display device according to an embodiment of the present disclosure.

FIG. 14 is a block diagram illustrating an electronic device according to an embodiment of the present disclosure.

FIG. 15 is a schematic view illustrating electronic devices according to embodiments of the present disclosure.

### DETAILED DESCRIPTION

Hereinafter, embodiments of the present disclosure will be described in more detail with reference to the accompanying drawings. The same reference numerals are used for the same components in the drawings, and redundant descriptions of the same components will be omitted.

Within the Figures and the text of the disclosure, a reference number indicating a singular form of an element may also be used to reference a plurality of the element.

It will be understood that when an element is referred to as being related to another element such as being “on” another element, it can be directly on the other element or intervening elements may be present therebetween. In contrast, when an element is referred to as being related to another element such as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

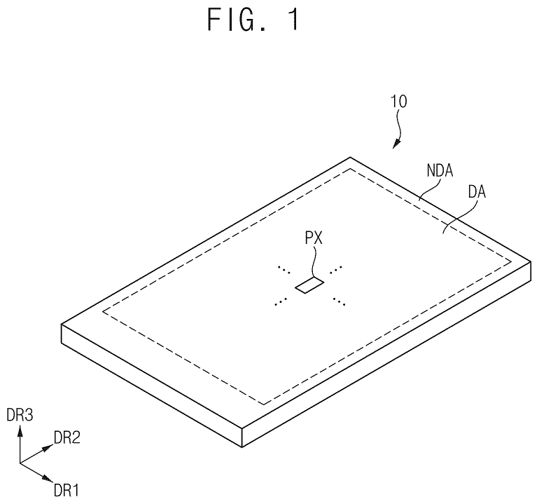

FIG. 1 is a perspective view illustrating a display device 10 according to an embodiment of the present disclosure.

Referring to FIG. 1, a display device 10 may include a display area DA and a non-display area NDA.

The display area DA may be an area (e.g., a planar area) which displays an image. A pixel PX provided in plural including a plurality of pixels PX may be arranged in the display area DA. The pixels PX may be arranged in a matrix form along a first direction DR1 and a second direction DR2 which intersects the first direction DR1. Each of the pixels PX may emit light. As each of the pixels PX emits light, the display area DA may display an image. For example, an image may be displayed in a third direction DR3 intersecting each of the first direction DR1 and the second direction DR2, in the display area DA. Lines connected to the pixels PX may be further arranged in the display area DA. For example, the lines as conductive lines and/or signal lines may include data signal lines, gate signal lines, power lines, or the like.

The non-display area NDA may be an area (e.g., a planar area) which does not display an image. The non-display area NDA is adjacent to the display area DA, and may be arranged around the display area DA. For example, the non-display area NDA may surround the display area DA in a plan view. The plan view may be defined along a direction intersecting or normal to a plane, such as a plane defined by the first direction DR1 and the second direction DR2 crossing each other in FIG. 1. A thickness of various components or layers of the display device 10 may be defined along the third direction DR3, e.g., a thickness direction.

Drivers for driving the pixels PX may be arranged in the non-display area NDA. For example, the drivers may include a data driver, a gate driver, a power voltage generator, a timing controller, or the like. The pixels PX may emit light based on signals received from the drivers.

The display device 10 may detect an external input applied from outside (e.g., outside of the display device 10). The external input may include various types of inputs provided from the outside of the display device 10. The external input may include not only contact (e.g., physical contact) from an input tool, but also an external input applied close to or adjacent to the display device 10 by a selectable distance. In addition, the external input may have various forms such as force, pressure, temperature, light, or the like. The input tool may include a body part, such as of a user's body, a pen or stylus, etc.

The display device 10 may sense biometric information of an external object (e.g., a user) which is applied from the outside. A biometric information sensing area which senses the user's biometric information may be provided in the display area DA of the display device 10. For example, the biometric information sensing area may be provided in or corresponding to an entire area (e.g., planar area) of the display area DA or in a partial area of the display area DA.

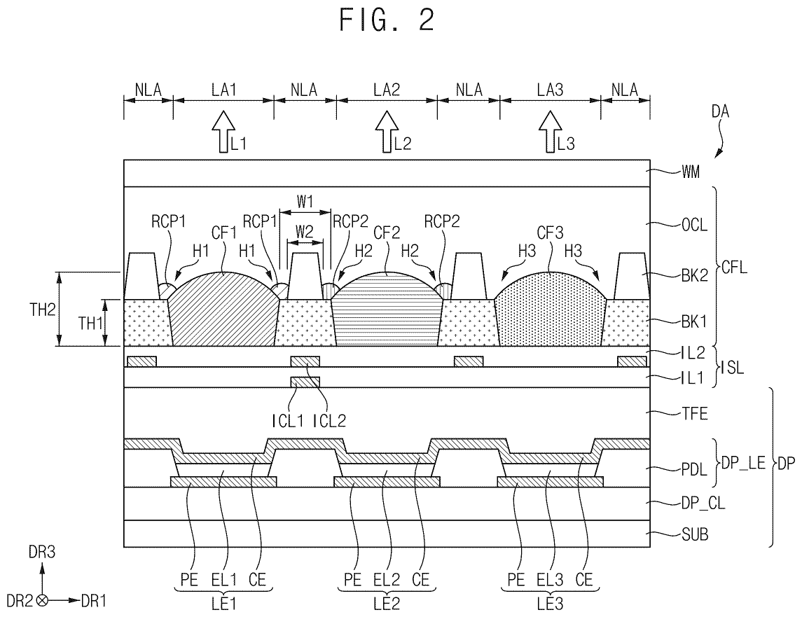

FIG. 2 is a cross-sectional view illustrating a portion of a display area DA of the display device 10 of FIG. 1.

Referring to FIGS. 1 and 2, the display area DA of the display device 10 may include a first light emitting area LA1, a second light emitting area LA2, a third light emitting area LA3, and a non-light emitting area NLA. Each of a light emitting area among the first light emitting area LA1, the second light emitting area LA2, and the third light emitting area LA3 may be an area (e.g., a planar) which emits light. As light is emitted at each of the first, second, and third light emitting areas LA1, LA2, and LA3, the display area DA may display an image. The first, second, and third light emitting areas LA1, LA2, and LA3 may correspond to the pixels PX, respectively. That is, the planar area of the light emitting element may define a planar area of a corresponding pixel PX.

In an embodiment, the first light emitting area LA1, the second light emitting area LA2, and the third light emitting area LA3 may emit light of different wavelength bands. The first light emitting area LA1 may emit first light L1, the second light emitting area LA2 may emit second light L2, and the third light emitting area LA3 may emit third light L3. For example, the first light L1 may be light of a red wavelength band, the second light L2 may be light of a green wavelength band, and the third light L3 may be light of a blue wavelength band, but the present disclosure is not limited thereto. In another embodiment, the first, second, and third light emitting areas LA1, LA2, and LA3 may emit light of same wavelength band, or at least one of the first, second, and third light emitting areas LA1, LA2, and LA3 may emit light of a different wavelength band.

Although FIG. 2 illustrates that the first, second, and third light emitting areas LA1, LA2, and LA3 are arranged along the first direction DR1, the present disclosure is not limited thereto, and an arrangement structure of the first, second, and third light emitting areas LA1, LA2, and LA3 may be variously modified.

The non-light emitting area NLA may be an area at which light is not emitted from the display area DA. The non-light emitting area NLA may partition the planar areas of the first, second, and third light emitting areas LA1, LA2, and LA3. The non-light emitting area NLA may be arranged between the first, second, and third light emitting areas LA1, LA2, and LA3 which are adjacent to each other. The non-light emitting area NLA may surround each of the first, second, and third light emitting areas LA1, LA2, and LA3 in a plan view, such as to be extended around all sides of the light emitting area.

The display device 10 may include a display panel layer DP, an input sensing layer ISL, a color filter layer CFL, and a window WM. The display panel layer DP may include a substrate SUB, a circuit layer DP_CL, an element layer DP_LE, and an encapsulation layer TFE.

The substrate SUB may include a transparent material or an opaque material. Examples of materials which may be used as the substrate SUB may include polyimide, quartz, glass, or the like. These may be used alone or in combination with each other.

The circuit layer DP_CL may be arranged on the substrate SUB. The circuit layer DP_CL may include a transistor, a capacitor, an insulating layer, a signal line, or the like.

The element layer DP_LE may be arranged on the circuit layer DP_CL. The element layer DP_LE may include a light emitting element provided in plural such as a first light emitting element LE1, a second light emitting element LE2 and a third light emitting element LE3, and a pixel defining layer PDL. The first light emitting element LE1 may include a pixel electrode PE as a first pixel electrode, a first light emitting layer EL1 and a common electrode CE, the second light emitting element LE2 may include the pixel electrode PE as a second pixel electrode, a second light emitting layer EL2 and the common electrode CE, and the third light emitting element LE3 may include the pixel electrode PE as a third pixel area, a third light emitting layer EL3 and the common electrode CE.

The pixel electrode PE may be arranged on the circuit layer DP_CL. The pixel electrode PE of the element layer DP-LE may be connected to the circuit layer DP_CL, such as at the transistor thereof. For example, the pixel electrode PE may be connected to the transistor through a contact hole penetrating a thickness of the insulating layer of the circuit layer DP_CL. The pixel electrode PE may include a metal, an alloy, a conductive metal oxide, a conductive metal nitride, a transparent conductive material, or the like. These may be used alone or in combination with each other.

The pixel defining layer PDL may be arranged in the non-light emitting area NLA, on the circuit layer DP_CL. The pixel defining layer PDL may include a pixel opening defined therein which exposes at least a portion of an upper surface of the pixel electrode PE disposed in the pixel opening. For example, the pixel defining layer PDL may cover a side surface of the pixel electrode PE and a portion of an upper surface thereof which is adjacent to the side surface. The first, second, and third light emitting areas LA1, LA2, and LA3 may be defined to correspond to the pixel electrode PE exposed by the pixel defining layer PDL, respectively, and the non-light emitting area NLA may be defined between the first, second, and third light emitting areas LA1, LA2, and LA3.

The pixel defining layer PDL may include an organic material such as a polyimide resin, an epoxy resin, a siloxane resin, or the like, or an inorganic material such as silicon oxide, silicon nitride, silicon oxynitride, or the like. These may be used alone or in combination with each other. In an embodiment, the pixel defining layer PDL may include a light blocking material. For example, the pixel defining layer PDL may implement a black pixel defining layer. The light blocking material may include carbon black, black dye, black pigment, metal (e.g., nickel, aluminum, molybdenum, and alloys thereof), metal oxide (e.g., chromium oxide), metal nitride (e.g., chromium nitride), or the like.

The first, second, and third light emitting layers EL1, EL2, and EL3 may be arranged on the pixel electrode PE within a layer of pixel electrodes, respectively. The first, second, and third light emitting layers EL1, EL2, and EL3 may be arranged in the first, second, and third light emitting areas LA1, LA2, and LA3, respectively. The first, second, and third light emitting layers EL1, EL2, and EL3 may be arranged on the pixel electrode PE exposed by the pixel defining layer PDL, respectively.

In an embodiment, the first, second, and third light emitting layers EL1, EL2, and EL3 may emit light of different wavelength bands. For example, the first light emitting layer EL1 may emit the first light L1, the second light emitting layer EL2 may emit the second light L2, and the third light emitting layer EL3 may emit the third light L3. In another embodiment, the first, second, and third light emitting layers EL1, EL2, and EL3 may emit light of same wavelength band, or at least one of the first, second, and third light emitting layers EL1, EL2, and EL3 may emit light of a different wavelength band.

For example, each of the first, second, and third light emitting layers EL1, EL2, and EL3 may include a light emitting layer including a material which emit light and an auxiliary layer (not shown) which is on the light emitting layer. The auxiliary layer may include at least one of a hole injection layer, a hole transport layer, an electron transport layer, and an electron injection layer.

The common electrode CE may be arranged on the pixel defining layer PDL and the first, second, and third light emitting layers EL1, EL2 and EL3. For example, the common electrode CE may continuously extend in the first, second, and third light emitting areas LA1, LA2, and LA3 and the non-light emitting area NLA. The common electrode CE may include a metal, an alloy, a conductive metal oxide, a conductive metal nitride, a transparent conductive material, or the like. These may be used alone or in combination with each other.

Accordingly, the first light emitting element LE1 including the pixel electrode PE, the first light emitting layer EL1 and the common electrode CE may be arranged in the first light emitting area LA1, on the substrate SUB, the second light emitting element LE2 including the pixel electrode PE, the second light emitting layer EL2 and the common electrode CE may be arranged in the second light emitting area LA2, on the substrate SUB, and the third light emitting element LE3 including the pixel electrode PE, the third light emitting layer EL3 and the common electrode CE may be arranged in the third light emitting area LA3, on the substrate SUB.

The encapsulation layer TFE may be arranged on the common electrode CE. The encapsulation layer TFE may prevent impurities, moisture, outside air, or the like from penetrating into the first, second, and third light emitting elements LE1, LE2, and LE3 from the outside. The encapsulation layer TFE may include at least one inorganic encapsulation layer and at least one organic encapsulation layer.

The input sensing layer ISL may be arranged on the display panel layer DP. For example, the input sensing layer ISL may be directly arranged on the encapsulation layer TFE. The input sensing layer ISL may sense the external input applied from the outside. The input sensing layer ISL may include a first conductive layer ICL1, a first input insulating layer IL1, a second conductive layer ICL2, and a second input insulating layer IL2. The input sensing layer ISL at the first input insulating layer IL1, may contact the display panel DP at the encapsulation layer TFE thereof.

The first conductive layer ICL1 may be arranged in the non-light emitting area NLA on the encapsulation layer TFE. The first conductive layer ICL1 may have a single layer structure or a multilayer structure, and may include a plurality of conductive patterns. The first conductive layer ICL1 may include a metal, an alloy, a transparent conductive material, or the like. These may be used alone or in combination with each other.

The first input insulating layer IL1 may be arranged on the first conductive layer ICL1, and may cover the first conductive layer ICL1. The first input insulating layer IL1 may be arranged in the first, second, and third light emitting areas LA1, LA2, and LA3 and the non-light emitting area NLA. The first input insulating layer IL1 may include an organic material such as an acrylic resin a polyimide resin, or the like, or an inorganic material such as silicon oxide, silicon nitride, silicon oxynitride, or the like. These may be used alone or in combination with each other.

The second conductive layer ICL2 may be arranged in the non-light emitting area NLA on the first input insulating layer IL1. The second conductive layer ICL2 may have a single layer structure or a multilayer structure, and may include a plurality of conductive patterns. Some of the plurality of conductive patterns of the second conductive layer ICL2 may be connected (e.g., electrically connected) to the first conductive layer ICL1. The second conductive layer ICL2 may include a metal, an alloy, a transparent conductive material, or the like. These may be used alone or in combination with each other.

The second input insulating layer IL2 may be arranged on the first input insulating layer IL1 and the second conductive layer ICL2, and may cover the first input insulating layer IL1 and the second conductive layer ICL2. The second input insulating layer IL2 may be arranged in the first, second, and third light emitting areas LA1, LA2, and LA3 and the non-light emitting area NLA. The second input insulating layer IL2 may include an organic material such as an acrylic resin, a polyimide resin, or the like, or an inorganic material such as silicon oxide, silicon nitride, silicon oxynitride, or the like. These may be used alone or in combination with each other.

Although FIG. 2 illustrates that the input sensing layer ISL includes the first and second conductive layers ICL1 and ICL2 and the first and second input insulating layers IL1 and IL2, the present disclosure is not limited thereto. For example, the input sensing layer ISL may further include a base insulating layer (not shown) arranged between the first conductive layer ICL1 and the encapsulation layer TFE, may include only one of the first and second conductive layers ICL1 and ICL2, or may not include the second input insulating layer IL2.

The color filter layer CFL as a color control (or color conversion) layer may be arranged on the input sensing layer ISL. The color filter layer CFL may include a first bank BK1 of a first bank layer, a first color filter CF1, a second color filter CF2, a third color filter CF3, a second bank BK2 of a second bank layer, a first reflection control pattern RCP1, a second reflection control pattern RCP2, and an overcoating layer OCL. The first bank layer together with the second bank layer may define a bank layer of the display device 10. The color filter faces the encapsulation layer TFE along the thickness direction.

The first bank BK1 of a bank (or a bank structure) as a solid portion (e.g., solid material portion) of the first bank layer may be arranged in the non-light emitting area NLA on the input sensing layer ISL. The first bank BK1 may define areas in which the first, second, and third color filters CF1, CF2, and CF3 are arranged. The first bank BK1 may define openings as first bank openings in which the first, second, and third color filters CF1, CF2, and CF3 are respectively arranged, and may surround each of the first, second, and third color filters CF1, CF2, and CF3 in a plan view.

In an embodiment, the first bank BK1 may include a light blocking material. The light blocking material may include carbon black, a black dye, a black pigment, a metal, a metal oxide, a metal nitride, or the like. In addition, the light blocking material may have liquid repellency with respect to a material included in the first, second, and third color filters CF1, CF2, and CF3. As the first bank BK1 includes the light blocking material, reflection of external light by lower components may be reduced, and color mixing between the first, second, and third light emitting areas LA1, LA2, and LA3 may be prevented.

The first bank BK1 may have a first thickness TH1 in the thickness direction. The first thickness TH1 may be a distance or height in the third direction DR3 from a first surface of the first bank BK1 which is closest to the input sensing layer ISL, to a second surface of the first bank BK1 which is furthest from the input sensing layer ISL and opposite to the first surface. In an embodiment, the first thickness TH1 may be a maximum thickness of the first bank layer.

The first bank BK1 may have a first width W1 in a width direction along a planar direction. The first width W1 may be a minimum length (or dimension) of the first bank BK1 in the first direction DR1. For example, the first width W1 may be a length in the first direction DR1 of the second surface of the first bank BK1. That is, a width of the first bank BK1 may increase in a direction from the second surface to the first surface. In an embodiment, the bank structure (e.g., the first bank layer together with the second bank layer) includes a first bank BK1 having a first width W1 in a width direction along the encapsulation layer TFE and a second bank BK2 which is on the first bank BK1 and has a second width W2 less than or equal to the first width W1 in the width direction. The width direction may be defined alone any of a number of planar directions of a plane, like the DR1-DR2 plane.

The first color filter CF1 may be arranged in the first light emitting area LA1, on the input sensing layer ISL. The first color filter CF1 may overlap the first light emitting element LE1 in a plan view. For example, the first color filter CF1 may be arranged to correspond to the first light emitting layer EL1. The first color filter CF1 may transmit the first light L1, and may block light of a wavelength band different from that of the first light L1. For example, the first color filter CF1 may transmit light of a red wavelength band, and may block light of a green wavelength band and a blue wavelength band, but the present disclosure is not limited thereto. Accordingly, the first light L1 may be emitted to the outside in the first light emitting area LA1 (e.g., in the third direction DR3).

The second color filter CF2 may be arranged in the second light emitting area LA2, on the input sensing layer ISL. The second color filter CF2 may overlap the second light emitting element LE2 in a plan view. For example, the second color filter CF2 may be arranged to correspond to the second light emitting layer EL2. The second color filter CF2 may transmit the second light L2, and may block light of a wavelength band different from that of the second light L2. For example, the second color filter CF2 may transmit light of a green wavelength band, and may block light of a red wavelength band and a blue wavelength band, but the present disclosure is not limited thereto. Accordingly, the second light L2 may be emitted to the outside in the second light emitting area LA2 (e.g., in the third direction DR3).

The third color filter CF3 may be arranged in the third light emitting area LA3, on the input sensing layer ISL. The third color filter CF3 may overlap the third light emitting element LE3 in a plan view. For example, the third color filter CF3 may be arranged to correspond to the third light emitting layer EL3. The third color filter CF3 may transmit the third light L3, and may block light of a wavelength band different from that of the third light L3. For example, the third color filter CF3 may transmit light of a blue wavelength band, and may block light of a red wavelength band and a green wavelength band, but the present disclosure is not limited thereto. Accordingly, the third light L3 may be emitted to the outside in the third light emitting area LA3 (e.g., in the third direction DR3). In an embodiment, within the display device 10, the light emitting element is provided in plural including a first light emitting element LE1 which emits first light L1 a second light emitting element LE2 which emits second light L2; and a third light emitting element LE3 which emits a third light L3. The color filter is provided in plural including a first color filter CF1 overlapping the first light emitting element LE1 along the thickness direction, a second color filter CF2 overlapping the second light emitting element LE2 in the thickness direction, and a third color filter CF3 overlapping the third light emitting element LE3 in the thickness direction.

The first, second, and third color filters CF1, CF2, and CF3 may have a second thickness TH2 in the thickness direction. More specifically, the first and second color filters CF1 and CF2 may have the second thickness TH2 in the thickness direction. The second thickness TH2 may be a length in the third direction DR3 from a surface adjacent to the input sensing layer ISL of the first, second, and third color filters CF1, CF2, and CF3 (more specifically, the first and second color filters CF1 and CF2) to a highest point spaced apart from the input sensing layer ISL of the first, second, and third color filters CF1, CF2, and CF3 (more specifically, the first and second color filters CF1 and CF2). For example, each of the first, second, and third color filters CF1, CF2, and CF3 may have a dome shape in a cross-sectional view. For example, each of the first, second, and third color filters CF1, CF2, and CF3 may be formed through an inkjet process. That is, a color filter is an inkjet pattern of a color filter material.

In an embodiment, the second thickness TH2 may be greater than the first thickness TH1. The second thickness TH2 may be a maximum dimension of a respective color filter. For example, the second thickness TH2 may be about 1 micrometer (μm) to about 2 micrometers (μm) greater than the first thickness TH1, but the present disclosure is not limited thereto.

The second bank BK2 of the bank (or the bank structure) may be arranged in the non-light emitting area NLA, on the first bank BK1. The second bank BK2 may define openings as second bank openings of the bank layer. A first bank opening may overlap a second bank opening to define a bank opening of the bank layer. In an embodiment, the second bank BK2 may include a liquid-repellent material. The second bank BK2 may have liquid repellency with respect to a material included in the first and second reflection control patterns RCP1 and RCP2. The second bank layer may protrude from the first bank layer within the overall bank layer of the display device 10.

The second bank BK2 may include a material different from that of the first bank BK1. For example, the second bank BK2 may include an organic material such as an acrylic resin, a polyimide resin, or the like, or an inorganic material such as silicon oxide, silicon nitride, silicon oxynitride, or the like. However, the present disclosure is not limited thereto, and the second bank BK2 may include various materials which control reflection from the first bank BK1. For example, the second bank BK2 may include a material having a surface roughness less than that of the first bank BK1, and accordingly, reflection on a surface of the first bank BK1 is reduced, thereby reducing reflection due to external light of the display device 10.

The second bank BK2 may have a second width W2 in the width direction. The second width W2 may be a maximum length of the second bank BK2 in the first direction DR1. For example, the second width W2 may be a length in the first direction DR1 of a surface of the second bank BK2 which is closest to the first bank BK1. In an embodiment, the second width W2 may be less than or equal to the first width W1. A step of the bank layer may be formed at a bank opening, by the first bank layer and the second bank layer. Here, side surfaces (or sidewalls) of each of the first bank layer and the second bank layer may define a bank opening.

As the second thickness TH2 of the first, second, and third color filters CF1, CF2, and CF3 may be greater than the first thickness TH1 of the first bank BK1, and the second width W2 of the second bank BK2 may be less than or equal to the first width W1 of the first bank BK1, a groove provided in plural including grooves at the stepped portions of the sidewalls may be defined between each of the first, second, and third color filters CF1, CF2, and CF3, and the second bank BK2, respectively. In an embodiment, a respective one of the groove is defined by surfaces of each of the color filter and the second bank BK2.

A first groove H1 may be defined between the first color filter CF1 and the second bank BK2, a second groove H2 may be defined between the second color filter CF2 and the second bank BK2, and a third groove H3 may be defined between the third color filter CF3 and the second bank BK2. Each groove may be defined by a sidewall of the second bank BK2, an upper surface of the first bank BK1 which forms a step with the sidewall of the second bank BK2 and an upper surface of a respective color filter, at a respective bank opening.

The first reflection control pattern RCP1 may be arranged in the first groove H1, and the second reflection control pattern RCP2 may be arranged in the second groove H2. For example, each of the first and second reflection control patterns RCP1 and RCP2 may be formed through an inkjet process. Each reflection control pattern may be a discrete pattern of a reflection material. That is, the reflection control pattern is an inkjet pattern of a reflective or reflection material.

In an embodiment, the first and second reflection control patterns RCP1 and RCP2 may have a color which corrects a color of reflected light as external light reflected within and/or from the display device 10. The first reflection control pattern RCP1 may include ink of a color which corrects a color of reflected light in the first light emitting area LA1, and the second reflection control pattern RCP2 may include ink of a color which corrects a color of reflected light in the second light emitting area LA2. For example, the first reflection control pattern RCP1 may include ink of a color which corrects a color of the first light L1 (e.g., red), and the second reflection control pattern RCP2 may include ink of a color which corrects a color of the second light L2 (e.g., green). For the reflection control pattern which ‘corrects’ a color of reflected light, a color of the reflection control pattern may be the same color as the color of the light which is emitted from the light emitting area, a color of the reflection control pattern may be a related color to the color of the light which is emitted from the light emitting area, the reflection pattern material may function to absorb or mask colors of light other than the colored light emitted from the light emitting area, the reflection pattern material may function to reflect the color of the light which is emitted from the light emitting area while minimizing reflection of other colors, etc. so as to reinforce the colored light emitted from the light emitting area and minimize other colors from being emitted at the light emitting area.

In an embodiment, a light emitted from the light emitting area has a color, and a color of a respective reflection control pattern is the same as the color of the light emitted from the light emitting area. For example, a color of the first reflection control pattern RCP1 is the same as a color of the first light L1, and a color of the second reflection control pattern RCP2 is the same as a color of the second light L2.

For example, each of the first and second reflection control patterns RCP1 and RCP2 may include ink of a primary color (e.g., red and green). Here, a color of the reflection control pattern may be the same color as the color of the light which is emitted from the light emitting area.

For another example, each of the first and second reflection control patterns RCP1 and RCP2 may include ink of a secondary color (e.g., cyan, magenta, yellow, or the like). Here, the reflection control pattern having the secondary color may be a color related to the color of the light which is emitted from the light emitting area, so as to reinforce reflection of the colored light emitted from the light emitting area while minimizing reflection of colors of light other than the colored light emitted from the light emitting area. In an embodiment, the respective reflection control pattern has a primary color including red or green, or a secondary color including cyan, magenta or yellow.

As the first reflection control pattern RCP1 is arranged adjacent to the first color filter CF1, and the second reflection control pattern RCP2 is arranged adjacent to the second color filter CF2, the first and second reflection control patterns RCP1 and RCP2 may affect color quality of reflected light when external light is reflected from the display device 10. For example, the color quality of the reflected light may be controlled to a color which provides comfort to a user of the display device 10. In addition, as the first and second reflection control patterns RCP1 and RCP2 include ink which corrects color quality of the first and second lights L1 and L2, respectively, a color reproducibility of the display device 10 may be improved.

The color, dimension, area, or the like of the first and second reflection control patterns RCP1 and RCP2 may not be limited, and may be variously adjusted depending on the color quality required by the display device 10, the shape, the planar area or the like of each of the first, second, and third light emitting areas LA1, LA2, and LA3, and the shape, the planar area, or the like of the first, second, and third color filters CF1, CF2, and CF3.

In an embodiment, the bank openings may each be an enclosed opening defined along a plane (e.g., the DR1-DR2 plane). Here, a solid material portion of the bank layer surrounds and defines the enclosed bank opening. A groove may surround a respective color filter such that the reflection material may form a reflection control pattern which surrounds the respective color filter. The reflection control pattern may have an enclosed shape surrounding an outer edge of the respective color filter, in the plan view.

The overcoating layer OCL may be arranged on the first, second, and third color filters CF1, CF2, and CF3, the first and second banks BK1 and BK2, and the first and second reflection control patterns RCP1 and RCP2. The overcoating layer OCL may include an organic material such as an acrylic resin, an epoxy resin, or the like. The overcoating layer OCL may have a selected thickness, and may planarize an upper surface of the color filter layer CFL.

The window WM may be arranged on the color filter layer CFL. The window WM may include an optically transparent material. For example, the window WM may include glass or plastic. The window WM may have a single layer structure or a multilayer structure. For example, the window WM may include a plurality of plastic films bonded with an adhesive, or may include a glass substrate and a plastic film bonded with an adhesive. The window WM may be bonded to the color filter layer CFL by an adhesive layer. For example, the adhesive layer may include an optically clear adhesive, an optically clear adhesive resin, a pressure sensitive adhesive, or the like.

The display device 10 according to an embodiment of the present disclosure may include the second bank BK2 arranged on the first bank BK1, and the first and second reflection control patterns RCP1 and RCP2 arranged in the first and second grooves H1 and H2 defined between the first and second color filters CF1 and CF2 and the second bank BK2, respectively. The second bank BK2 may reduce reflection from the first bank BK1, and the first and second reflection control patterns RCP1 and RCP2 may correct color quality of reflected light. Accordingly, reflection of external light of the display device 10 may be reduced, and color quality of reflection of the display device 10 may be improved.

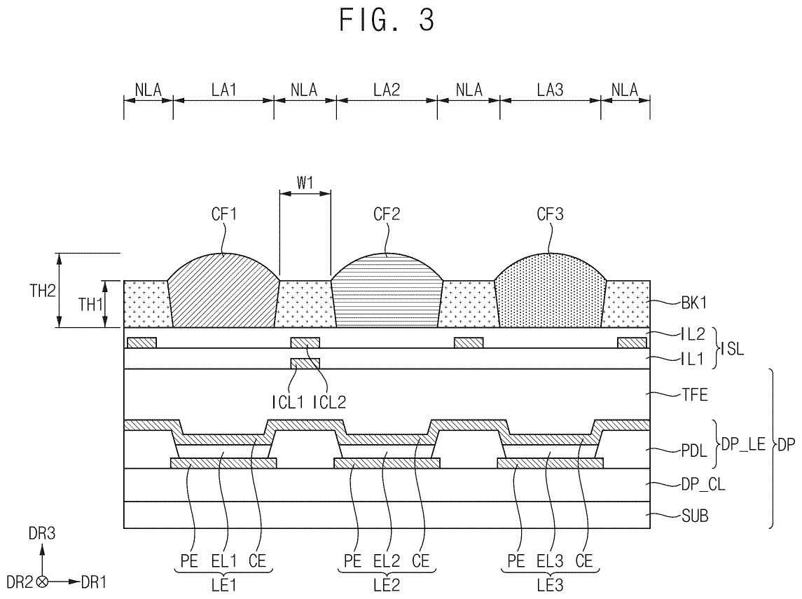

FIGS. 3, 4, 5, and 6 are enlarged cross-sectional views illustrating processes in a method of manufacturing (or providing) a display device 10 according to an embodiment of the present disclosure.

A method of manufacturing (or providing) a display device 10 described with reference to FIGS. 3, 4, 5, and 6 may be a method of manufacturing the display device 10 described with reference to FIGS. 1 and 2. Hereinafter, redundant descriptions will be omitted or simplified.

Referring to FIG. 3, the circuit layer DP_CL, the pixel electrode PE, the pixel defining layer PDL, the first, second, and third light emitting layers EL1, EL2, and EL3, the common electrode CE, the encapsulation layer TFE, the first conductive layer ICL1, the first input insulating layer IL1, the second conductive layer ICL2, and the second input insulating layer IL2 may be sequentially formed (or provided) on the substrate SUB. Accordingly, the input sensing layer ISL may be formed on the display panel layer DP.

The first bank BK1 of the first bank layer may be formed in the non-light emitting area NLA, on the input sensing layer ISL, to define first bank openings of the first bank layer which correspond to the light emitting areas. The first bank BK1 may be formed to have the first thickness TH1 in the third direction DR3 and to have the first width W1 in the first direction DR1. The first bank BK1 may include a light blocking material, and may have liquid repellency with respect to a material included in the first, second, and third color filters CF1, CF2, and CF3. The first width W1 defines a first bank opening width between adjacent portions of the first bank BK1.

The first color filter CF1 may be formed in the first light emitting area LA1, on the input sensing layer ISL, the second color filter CF2 may be formed in the second light emitting area LA2, on the input sensing layer ISL, and the third color filter CF3 may be formed in the third light emitting area LA3, on the input sensing layer ISL.

In an embodiment, the first, second, and third color filters CF1, CF2, and CF3 may selectively transmit light of different wavelength bands. The first color filter CF1 may selectively transmit first light (e.g., the first light L1 of FIG. 2), the second color filter CF2 may selectively transmit second light (e.g., the second light L2 of FIG. 2), and the third color filter CF3 may selectively transmit a third light (e.g., the third light L3 of FIG. 2). For example, the first color filter CF1 may transmit light of a red wavelength band, the second color filter CF2 may transmit light of a green wavelength band, and the third color filter CF3 may transmit light of a blue wavelength band.

The first, second, and third color filters CF1, CF2, and CF3 (more specifically, the first and second color filters CF1 and CF2) may be formed to have the second thickness TH2 in the third direction DR3. In an embodiment, the second thickness TH2 may be greater than the first thickness TH1. For example, each of the first, second, and third color filters CF1, CF2, and CF3 may be formed to have a dome shape in a cross-sectional view. In an embodiment, the color filters may be respectively formed in the first bank openings before providing of the second bank layer. A preliminary color control layer may include the first bank layer and the color filters on the input sensing layer ISL.

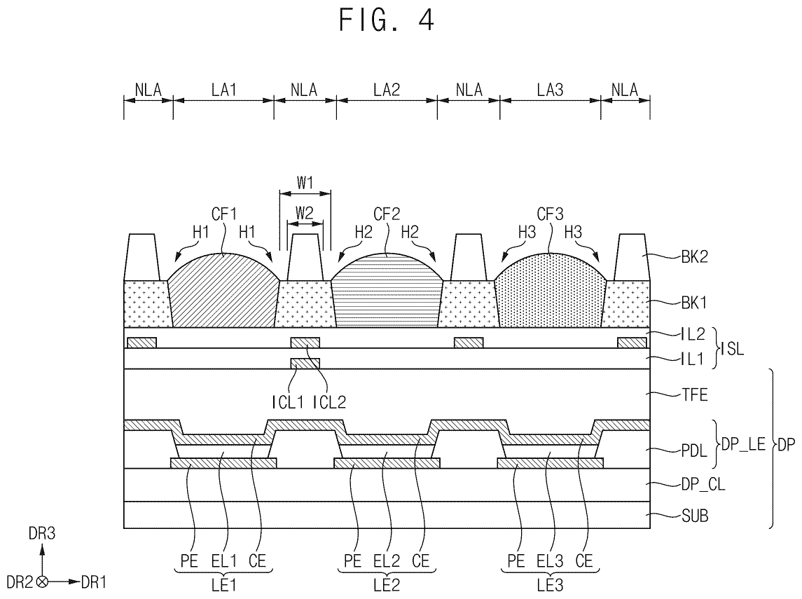

Referring to FIG. 4, the second bank BK2 may be formed in the non-light emitting area NLA, on the first bank BK1 of the preliminary color control layer, to define second bank openings of the second bank layer which respectively overlap the first bank openings. The second bank BK2 may be formed to have the second width W2 in the first direction DR1. The second width W2 defines a second bank opening width between adjacent portions of the second bank BK2. The second bank opening width may be greater than the first bank opening width, to provide a step of the bank layer.

As the second bank BK2 is formed, the groove may be defined between each of the first, second, and third color filters CF1, CF2, and CF3, and the second bank BK2, respectively. The first groove H1 may be formed between the first color filter CF1 and the second bank BK2, the second groove H2 may be formed between the second color filter CF2 and the second bank BK2, and the third groove H3 may be formed between the third color filter CF3 and the second bank BK2. Since the color filter at a respective bank opening protrudes upwardly from the first bank BK1, The step of the bank layer together with an upper surface of the upwardly-protruding defines a groove at the respective bank opening.

The first bank BK1 may be formed of a material different from that of the first bank BK1. The second bank BK2 may be formed of various materials which control reflection from the first bank BK1. For example, the second bank BK2 may include an organic material such as an acrylic resin, a polyimide resin, or the like, or an inorganic material such as silicon oxide, silicon nitride, silicon oxynitride, or the like. In addition, the second bank BK2 may be formed of a liquid-repellent material. The second bank BK2 may have liquid repellency with respect to a material included in the first and second reflection control patterns RCP1 and RCP2.

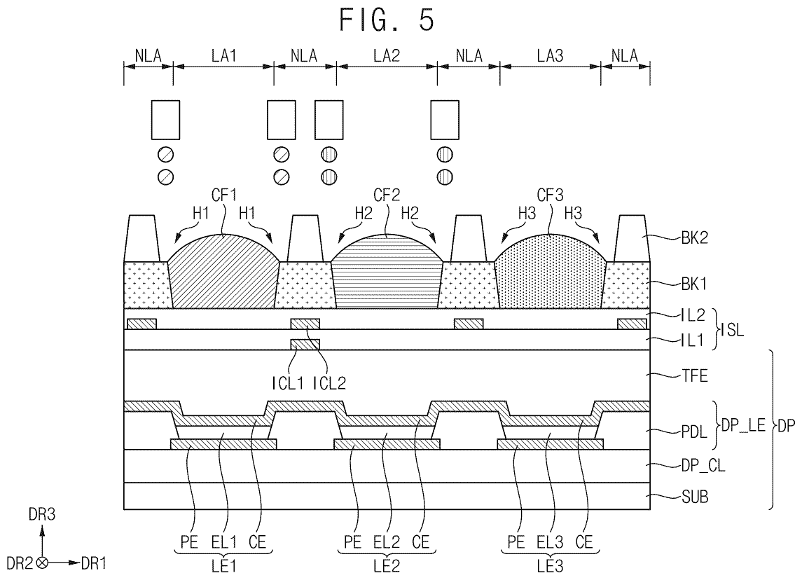

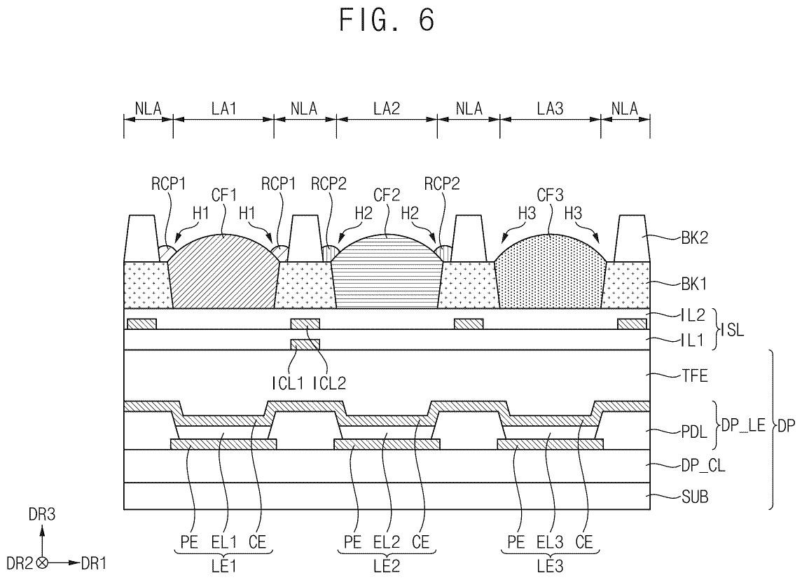

Referring to FIGS. 5 and 6, the first reflection control pattern RCP1 may be formed in the first groove H1, and the second reflection control pattern RCP2 may be formed in the second groove H2.

In an embodiment, the first and second reflection control patterns RCP1 and RCP2 may have a color which corrects a color of reflected light. For example, the first reflection control pattern RCP1 may be formed in the first groove H1 by dropping and curing ink of a color which corrects a color of reflected light in the first light emitting area LA1, and the second reflection control pattern RCP2 may be formed in the second groove H2 by dropping and curing ink of a color which corrects a color of reflected light in the second light emitting area LA2. For example, the first reflection control pattern RCP1 may be formed of ink of a color which corrects red, and the second reflection control pattern RCP2 may be formed of ink of a color which corrects green. For example, each of the first and second reflection control patterns RCP1 and RCP2 may be formed of ink of a primary color or a secondary color.

In an embodiment, within a respective bank opening (or light emitting area), the providing of reflection control material at a groove may provide a continuous reflection pattern extended along an outer edge of the color filter. Such continuous pattern may form a closed shape having a shape corresponding to a shape of the outer edge of the color filter in the plan view. The reflection pattern may overlap an outer edge of the color filter and expose the color filter to outside the reflection pattern, at the light emitting area.

An order in which the first and second reflection control patterns RCP1 and RCP2 are formed may not be limited. For example, by forming the first reflection control pattern RCP1, irradiating external light to observe reflected light such as in an inspection process, and then forming the second reflection control pattern RCP2, irradiating external light to observe reflected light such as in an inspection process, color quality of reflected light may be adjusted. For another example, by forming the second reflection control pattern RCP2, irradiating external light to observe reflected light, and then forming the first reflection control pattern RCP1, irradiating external light to observe reflected light, color quality of reflected light may be adjusted

Referring back to FIG. 2, the overcoating layer OCL may be formed on the first, second, and third color filters CF1, CF2, the first and second banks BK1 and BK2, and the first and second reflection control patterns RCP1 and RCP2 to form the color filter layer CFL.

The window WM may be formed on the color filter layer CFL, and accordingly, the display device 10 illustrated in FIG. 2 may be manufactured.

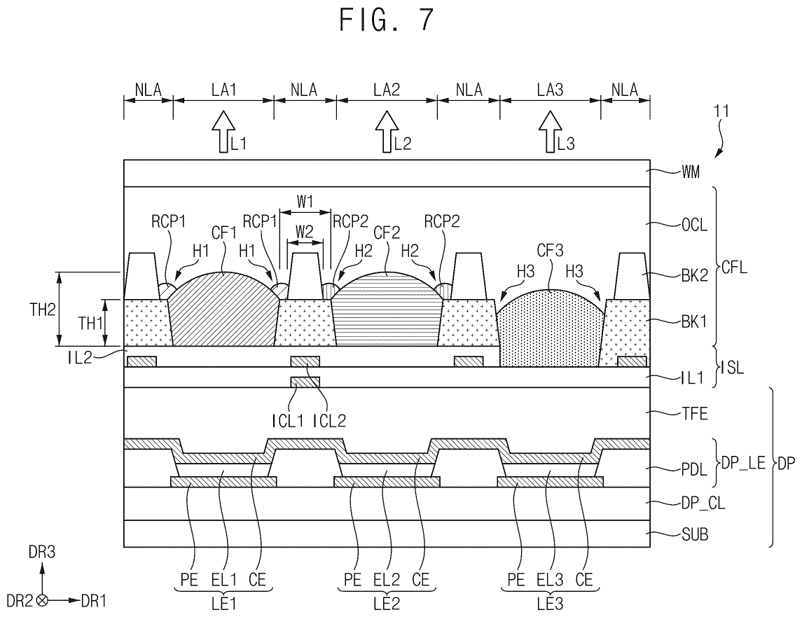

FIG. 7 is a cross-sectional view illustrating a display device 11 according to an embodiment of the present disclosure.

A display device 11 described with reference to FIG. 7 may be substantially same as or similar to the display device 10 described with reference to FIGS. 1 and 2 except for the second input insulating layer IL2. Hereinafter, redundant descriptions will be omitted or simplified.

Referring to FIG. 7, the display device 11 may include a first light emitting area LA1, a second light emitting area LA2, a third light emitting area LA3, and a non-light emitting area NLA. Each of the first, second, and third light emitting areas LA1, LA2, and LA3 may be an area which emits light, and the non-light emitting area NLA may be an area which does not emit light.

In an embodiment, the first, second, and third light emitting areas LA1, LA2, and LA3 may emit light of different wavelength bands. The first light emitting area LA1 may emit first light L1, the second light emitting area LA2 may emit second light L2, and the third light emitting area LA3 may emit third light L3. For example, the first light L1 may be light of a red wavelength band, the second light L2 may be light of a green wavelength band, and the third light L3 may be light of a blue wavelength band, but the present disclosure is not limited thereto.

The display device 11 may include a display panel layer DP, an input sensing layer ISL, a color filter layer CFL, and a window WM.

The display panel layer DP may include a substrate SUB, a circuit layer DP_CL, an element layer DP_LE, and an encapsulation layer TFE. The input sensing layer ISL may be arranged on the display panel layer DP, and may include a first conductive layer ICL1, a first input insulating layer IL1, a second conductive layer ICL2, and a second input insulating layer IL2.

The first conductive layer ICL1 may be arranged in the non-light emitting area NLA, on the display panel layer DP, and may include a plurality of conductive patterns.

The first input insulating layer IL1 may be arranged on the first conductive layer ICL1, and may cover the first conductive layer ICL1.

The second conductive layer ICL2 may be arranged in the non-light emitting area NLA, on the first input insulating layer IL1, and may include a plurality of conductive patterns. Some of the plurality of conductive patterns of the second conductive layer ICL2 may be connected to the first conductive layer ICL1.

The second input insulating layer IL2 may be arranged on the first input insulating layer IL1 and the second conductive layer ICL2, and may cover at least a portion of each of the first input insulating layer IL1 and the second conductive layer ICL2.

In an embodiment, the second input insulating layer IL2 may be arranged in the first and second light emitting areas LA1 and LA2, and may not be arranged in the third light emitting area LA3. For example, the second input insulating layer IL2 may be arranged in the first and second light emitting areas LA1 and LA2 which emit light of a relatively long wavelength band, and may be non-overlapping with the third light emitting area LA3 which emits light of a relatively short wavelength band. In addition, the second input insulating layer IL2 may be arranged in at least a portion of the non-light emitting area NLA. An area at which the second input insulating layer IL2 is not disposed may form a recess in the second input insulating layer IL2.

In an embodiment, the second input insulating layer IL2 may include scattering particles. The scattering particles may be dispersed in the second input insulating layer IL2. For example, the scattering particles may include titanium oxide (TiO₂), zinc oxide (ZnO), zirconium oxide (ZrO₂), aluminum oxide (Al₂O₃), cerium oxide (CrO₂), silicon oxide (SiO₂), or the like. The scattering particles may be spherical, elliptical, or amorphous. Average diameter, content, or the like of the scattering particles may not be limited, and may be variously adjusted depending on light extraction efficiency of the display device 11, characteristics of the second input insulating layer IL2, or the like.

The scattering particles may scatter light reflected from lower components and advances to outside, thereby preventing a color band due to reflection from being visually recognized or reducing a degree of being visually recognized. In addition, as the scattering particles are not arranged in the third light emitting area LA3 which emits the third light L3, a decrease in light extraction efficiency of the display device 11 may be minimized.

Although FIG. 7 illustrates that the second input insulating layer IL2 is not arranged in the third light emitting area LA3, the present disclosure is not limited thereto, and in an embodiment, the second input insulating layer IL2 including the scattering particles may be further arranged in the third light emitting area LA3.

The color filter layer CFL may be arranged on the input sensing layer ISL, and may include a first bank BK1, a first color filter CF1, a second color filter CF2, a third color filter CF3, a second bank BK2, a first reflection control pattern RCP1, a second reflection control pattern RCP2, and an overcoating layer OCL.

The first bank BK1 may be arranged in the non-light emitting area NLA, on the input sensing layer ISL. For example, when the second input insulating layer IL2 does not cover a portion of the second conductive layer ICL2, the first bank BK1 may cover the portion of the second conductive layer ICL2. Here, the first bank BK1 may extend to contact the first input insulating layer IL1 and provide a first bank opening at the third light emitting area LA3. A depth of the first bank opening at the third light emitting area LA3 may be greater than a depth of the first bank opening at the first or second light emitting areas LA1 and LA2. That is, the first bank BK1 may extend into the recess of the second input insulating layer IL2.

In an embodiment, the first bank BK1 may include a light blocking material, and may have liquid repellency with respect to a material included in the first, second, and third color filters CF1, CF2, and CF3. The first bank BK1 may have a first width W1 in the first direction DR1, and may have a first thickness TH1 in the third direction DR3. The first thickness TH1 may be a length in the third direction DR3 of the first bank BK1 overlapping the second input insulating layer IL2 in a plan view. That is, where the upper surface of the second input insulating layer IL2 is used as a reference, the first bank BK1 may have at least the first thickness TH1.

The first color filter CF1 may be arranged in the first light emitting area LA1, on the input sensing layer ISL, the second color filter CF2 may be arranged in the second light emitting area LA2, on the input sensing layer ISL, and the third color filter CF3 may be arranged in the third light emitting area LA3, on the input sensing layer ISL. The third color filter CF3 may extend into the recess of the second input insulating layer IL2. Within the first bank layer, an entire width of the first bank BK1 at a side of the third light emitting area LA3 may be within the recess of the second input insulating layer IL2, a partial width of the first bank BK1 adjacent to of the first bank BK1 at a side of the third light emitting area LA3 may be within the recess of the second input insulating layer IL2 while a remaining width portion extends from the recess and onto an upper surface of the second input insulating layer and/or an entire width of the first bank BK1 at a side of the third light emitting area LA3 may be outside of the recess of the second input insulating layer IL2 (e.g., the left first bank BK1 in FIG. 7).

The first color filter CF1 may selectively transmit the first light L1, the second color filter CF2 may selectively transmit the second light L2, and the third color filter CF3 may selectively transmit the third light L3.

The first, second, and third color filters CF1, CF2, and CF3 (more specifically, the first and second color filters CF1 and CF2) may have a second thickness TH2 in the third direction DR3. Here, the second thickness TH2 may be defined with the reference as the upper surface of the second input insulating layer IL2. In an embodiment, the second thickness TH2 may be greater than the first thickness TH1. Since the depth of the bank opening at the third light emitting are LA3 is increased by omission of the second input insulating layer IL2 at the third light emitting area LA3, a total thickness of the third color filer CF3 may be greater than a total thickness of other color filters. However, a total thickness of the third color filter CF3 still defines a third groove H3 together with a step of the bank layer which is exposed to the bank opening of the third light emitting area LA3.

The second bank BK2 may be arranged in the non-light emitting area NLA, on the first bank BK1. In an embodiment, the second bank BK2 may have liquid repellency with respect to a material included in the first and second reflection control patterns RCP1 and RCP2. The second bank BK2 may include various materials which control reflection from the first bank BK1. The second bank BK2 may have a second width W2 in the first direction DR1. In an embodiment, the second width W2 may be less than or equal to the first width W1.

As the second thickness TH2 may be greater than the first thickness TH1 and the second width W2 may be less than or equal to the first width W1, a first groove H1 may be defined between the first color filter CF1 and the second bank BK2, a second groove H2 may be defined between the second color filter CF2 and the second bank BK2, and a third groove H3 may be defined between the third color filter CF3 and the second bank BK2.

The first reflection control pattern RCP1 may be arranged in the first groove H1, and the second reflection control pattern RCP2 may be arranged in the second groove H2.

In an embodiment, the first and second reflection control patterns RCP1 and RCP2 may have a color which corrects a color of reflected light when external light is reflected from the display device 11. The first reflection control pattern RCP1 may include ink of a color which corrects a color of reflected light in the first light emitting area LA1, and the second reflection control pattern RCP2 may include ink of a color which corrects a color of reflected light in the second light emitting area LA2. For example, each of the first and second reflection control patterns RCP1 and RCP2 may include ink of a primary color or a secondary color.

When external light is reflected from the display device 11, the first and second reflection control patterns RCP1 and RCP2 may affect a color of reflected light. In addition, a color reproducibility of the display device 11 may be improved by the first and second reflection control patterns RCP1 and RCP2.

The overcoating layer OCL may be arranged on the first, second, and third color filters CF1, CF2 and CF3, the first and second banks BK1 and BK2, and the first and second reflection control patterns RCP1 and RCP2, and the window WM may be arranged on the color filter layer CFL.

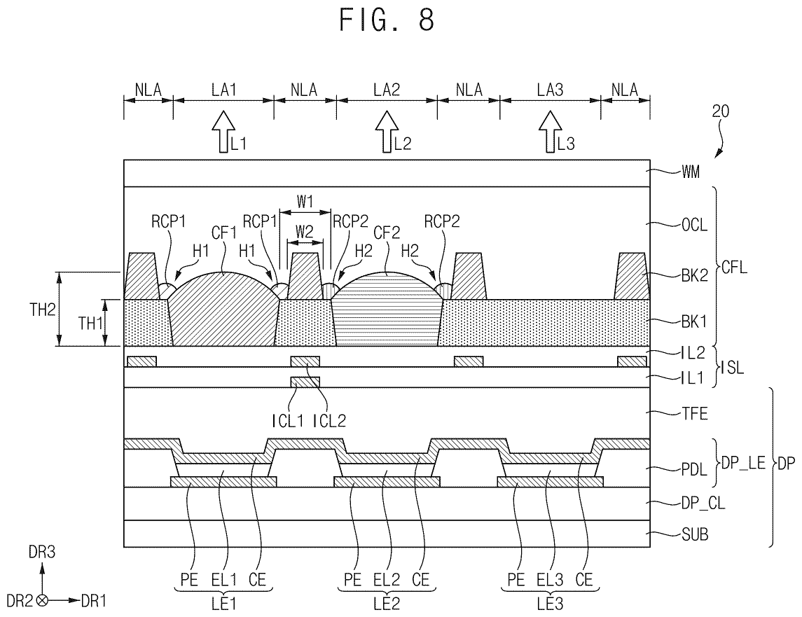

FIG. 8 is a cross-sectional view illustrating a display device 20 according to an embodiment of the present disclosure.

A display device 20 described with reference to FIG. 8 may be substantially same as or similar to the display device 10 described with reference to FIGS. 1 and 2 except for the color filter layer CFL. Hereinafter, redundant descriptions will be omitted or simplified.

Referring to FIG. 8, the display device 20 may include a first light emitting area LA1, a second light emitting area LA2, a third light emitting area LA3, and a non-light emitting area NLA. Each of the first, second, and third light emitting areas LA1, LA2, and LA3 may be an area which emits light, and the non-light emitting area NLA may be an area which does not emit light.

In an embodiment, the first, second, and third light emitting areas LA1, LA2, and LA3 may emit light of different wavelength bands. The first light emitting area LA1 may emit first light L1, the second light emitting area LA2 may emit second light L2, and the third light emitting area LA3 may emit third light L3. For example, the first light L1 may be light of a red wavelength band, the second light L2 may be light of a green wavelength band, and the third light L3 may be light of a blue wavelength band, but the present disclosure is not limited thereto.

The display device 20 may include a display panel layer DP, an input sensing layer ISL, a color filter layer CFL, and a window WM. The display panel layer DP may include a substrate SUB, a circuit layer DP_CL, an element layer DP_LE, and an encapsulation layer TFE.

The input sensing layer ISL may be arranged on the display panel layer DP. The input sensing layer ISL may include a first conductive layer ICL1, a first input insulating layer IL1, a second conductive layer ICL2, and a second input insulating layer IL2.

The color filter layer CFL may be arranged on the input sensing layer ISL. The color filter layer CFL may include a first bank BK1, a first color filter CF1, a second color filter CF2, a second bank BK2, a first reflection control pattern RCP1, a second reflection control pattern RCP2, and an overcoating layer OCL.

The first bank BK1 may be arranged in the third light emitting area LA3 and the non-light emitting area NLA, on the input sensing layer ISL. The first bank BK1 may define areas in which the first and second color filters CF1 and CF2 are arranged. The first bank BK1 may define openings in which the first and second color filters CF1 and CF2 are respectively arranged, and may surround each of the first and second color filters CF1 and CF2 in a plan view.

The first bank BK1 may have a first width W1 in the first direction DR1 and a first thickness TH1 in the third direction DR3, at areas adjacent to the first and second light emitting areas LA1 and LA2. The first width W1 may be a length in the first direction DR1 of the first bank BK1 arranged in the non-light emitting area NLA between the first and second light emitting areas LA1 and LA2.

The first bank BK1 adjacent to the third light emitting area LA3 may continuously extend from the non-light emitting area NLA and into the third light emitting area LA3 to overlap the third light emitting area LA3. An extended portion of the first bank BK1 may overlap an entirety of the third light emitting area LA3.

In an embodiment, the extended portion of the first bank BK1 may transmit the third light L3, and may block light of a wavelength band different from that of the third light L3. The first bank BK1 may selectively transmit light of a relatively short wavelength band. For example, the first bank BK1 may transmit light of a blue wavelength band, and may block light of a red wavelength band and a green wavelength band, but the present disclosure is not limited thereto. Accordingly, the third light L3 may be emitted to outside in the third light emitting area LA3 (e.g., in the third direction DR3). Here, the extended portion of the first bank BK1 may have a third color filter function while the third color filter CF3 as described for other embodiments is excluded from the third light emitting area LA3.

The first color filter CF1 may be arranged in the first light emitting area LA1, on the input sensing layer ISL. The first color filter CF1 may transmit the first light L1, and may block light of a wavelength band different from that of the first light L1. For example, the first color filter CF1 may transmit light of a red wavelength band, and may block light of a green wavelength band and a blue wavelength band, but the present disclosure is not limited thereto.

The second color filter CF2 may be arranged in the second light emitting area LA2, on the input sensing layer ISL. The second color filter CF2 may transmit the second light L2, and may block light of a wavelength band different from that of the second light L2. For example, the second color filter CF2 may transmit light of a green wavelength band, and may block light of a red wavelength band and a blue wavelength band, but the present disclosure is not limited thereto.

The first and second color filters CF1 and CF2 may have a second thickness TH2 in the third direction DR3. For example, each of the first and second color filters CF1 and CF2 may have a dome shape in a cross-sectional view. In an embodiment, the second thickness TH2 may be greater than the first thickness TH1.

The second bank BK2 may be arranged in the non-light emitting area NLA, on the first bank BK1. The second bank BK2 may transmit the first light L1, and may block light of a wavelength band different from that of the first light L1. For example, the second bank BK2 may include a same material as the first color filter CF1. For example, the second bank BK2 may transmit light of a red wavelength band, and may block light of a green wavelength band and a blue wavelength band, but the present disclosure is not limited thereto.

As the first bank BK1 which selectively transmits the third light L3 and the second bank BK2 which selectively transmits the first light L1 are stacked in the non-light emitting area NLA, reflection of external light due to lower components reflecting light may be reduced, and color mixing between the first, second, and third light emitting areas LA1, LA2, and LA3 may be prevented. In addition, reflection from a surface of the first bank BK1 may be reduced, thereby reducing reflection due to external light of the display device 20.

Although FIG. 8 illustrates that the first bank BK1 which transmits the third light L3 and the second bank BK2 which transmits the first light L1 are stacked in the non-light emitting area NLA, the present disclosure is not limited thereto. For example, various modified structures may be applied to prevent color mixing between the first, second, and third light emitting areas LA1, LA2, and LA3 and to reduce reflection of external light of the display device 20, such as by further stacking a bank material which transmits the second light L2 in the non-light emitting area NLA.

The second bank BK2 may have a second width W2 in the first direction DR1. In an embodiment, the second width W2 may be less than or equal to the first width W1.

As the second thickness TH2 of the first and second color filters CF1 and CF2 may be greater than the first thickness TH1 of the first bank BK1 and the second width W2 of the second bank BK2 may be less than or equal to the first width W1 of the first bank BK1, a first groove H1 may be defined between the first color filter CF1 and the second bank BK2, and a second groove H2 may be defined between the second color filter CF2 and the second bank BK2.

The first reflection control pattern RCP1 may be arranged in the first groove H1, and the second reflection control pattern RCP2 may be arranged in the second groove H2. For example, the first and second reflection control patterns RCP1 and RCP2 may be formed through an inkjet process.

In an embodiment, the first and second reflection control patterns RCP1 and RCP2 may have a color which corrects a color of reflected light when external light is reflected from the display device 20. The first reflection control pattern RCP1 may include ink of a color which corrects a color of reflected light in the first light emitting area LA1, and the second reflection control pattern RCP2 may include ink of a color which corrects a color of reflected light in the second light emitting area LA2. For example, the first reflection control pattern RCP1 may include ink of a color which corrects a color of the first light L1 (e.g., red), and the second reflection control pattern RCP2 may include ink of a color which corrects a color of the second light L2 (e.g., green). For example, each of the first and second reflection control patterns RCP1 and RCP2 may include ink of a primary color or a secondary color.

As the first and second reflection control patterns RCP1 and RCP2 are arranged adjacent to the first and second color filters CF1 and CF2, respectively, the first and second reflection control patterns RCP1 and RCP2 may affect color quality of reflected light when external light is reflected from the display device 20. For example, the color quality of the reflected light may be controlled to a color which gives comfort to a user. In addition, as the first and second reflection control patterns RCP1 and RCP2 include ink which corrects color quality of the first and second lights L1 and L2, a color reproducibility of the display device 20 may be improved. Since a third color filter CF3 is omitted at the third light emitting area LA3, no groove is formed adjacent thereto and within the bank opening.

The overcoating layer OCL may be arranged on the first and second color filters CF1 and CF2, the first and second banks BK1 and BK2, and the first and second reflection control patterns RCP1 and RCP2, and the window WM may be arranged on the color filter layer CFL.

The display device 20 according to an embodiment of the present disclosure may include the first bank BK1 arranged in the third light emitting area LA3 and the non-light emitting area NLA, and the first and second reflection control patterns RCP1 and RCP2 arranged in the first and second grooves H1 and H2 defined between the first and second color filters CF1 and CF2 and the second bank BK2, respectively. Reflection from the first bank BK1 may be reduced, and the first and second reflection control patterns RCP1 and RCP2 may correct color quality of reflected light. Accordingly, reflection of external light of the display device 20 may be reduced, and color quality of reflection of the display device 20 may be improved.

In addition, as an extended portion of the first bank BK1 is formed overlapping the third light emitting area LA3 and the non-light emitting area NLA, a separate process of forming a color filter which selectively transmits the third light L3 in the third light emitting area LA3 may not be required. Accordingly, manufacturing process of the display device 20 may be relatively simplified.

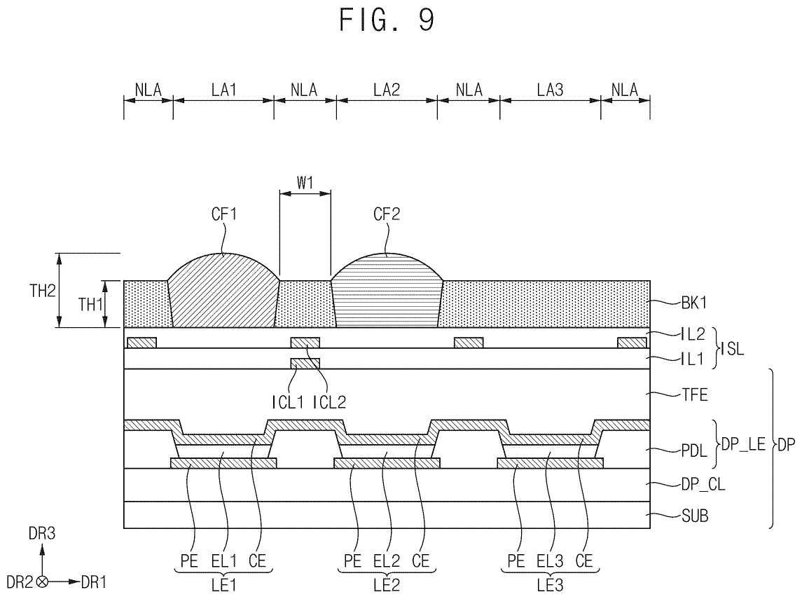

FIGS. 9, 10, 11, and 12 are enlarged cross-sectional views illustrating processes in a method of manufacturing (or providing) a display device 20 according to an embodiment of the present disclosure.

A method of manufacturing (or providing) a display device 20 described with reference to FIGS. 9, 10, 11, and 12 may be a method of manufacturing the display device 20 described with reference to FIG. 8. Hereinafter, redundant descriptions will be omitted or simplified.

Referring to FIG. 9, the input sensing layer ISL may be formed on the display panel layer DP.

The first bank BK1 may be formed in the third light emitting area LA3 and the non-light emitting area NLA, on the input sensing layer ISL. In an embodiment, the first bank BK1 may be simultaneously formed in the third light emitting area LA3 and the non-light emitting area NLA. The first bank BK1 and the third color filter as a portion of the first bank BK1 which overlaps the third light emitting area LA3 are in a same layer as each other. In an embodiment, the first bank BK1 extends from the non-light emitting area NLA to overlap the third light emitting element LE3 and defines the third color filter. As being in a same layer, elements may be formed in a same process and/or include a same material as each other, elements may be respective portions of a same material layer, elements may be on a same layer by forming an interface with a same underlying or overlying layer, elements may be coplanar with each other or be disposed in a same thickness, etc., without being limited thereto. That is, the third color filter and the first bank BK1 are respective portions of a same material layer.

The first bank BK1 may be formed to have the first thickness TH1 in the third direction DR3 and to have the first width W1 in the first direction DR1. The first width W1 may be a length in the first direction DR1 of the first bank BK1 arranged in the non-light emitting area NLA between the first and second light emitting areas LA1 and LA2.

The first color filter CF1 may be formed in the first light emitting area LA1, on the input sensing layer ISL, and the second color filter CF2 may be formed in the second light emitting area LA2, on the input sensing layer ISL. A separate color filter as the third color filter CF3 may be omitted, owing to a color filter function of the first bank BK1 overlapping the third light emitting area LA3.

In an embodiment, the first and second color filters CF1 and CF2 and the first bank BK1 may selectively transmit light of different wavelength bands. The first color filter CF1 may selectively transmit first light (e.g., the first light L1 of FIG. 8), the second color filter CF2 may selectively transmit second light (e.g., the second light L2 of FIG. 8), and the first bank BK1 may selectively transmit third light (e.g., the third light L3 of FIG. 8) to have a color filter function. For example, the first color filter CF1 may selectively transmit light of a red wavelength band, the second color filter CF2 may selectively transmit light of a green wavelength band, and the first bank BK1 may selectively transmit light of a blue wavelength band.

The first and second color filters CF1 and CF2 may be formed to have the second thickness TH2 in the third direction DR3. In an embodiment, the second thickness TH2 may be greater than the first thickness TH1.

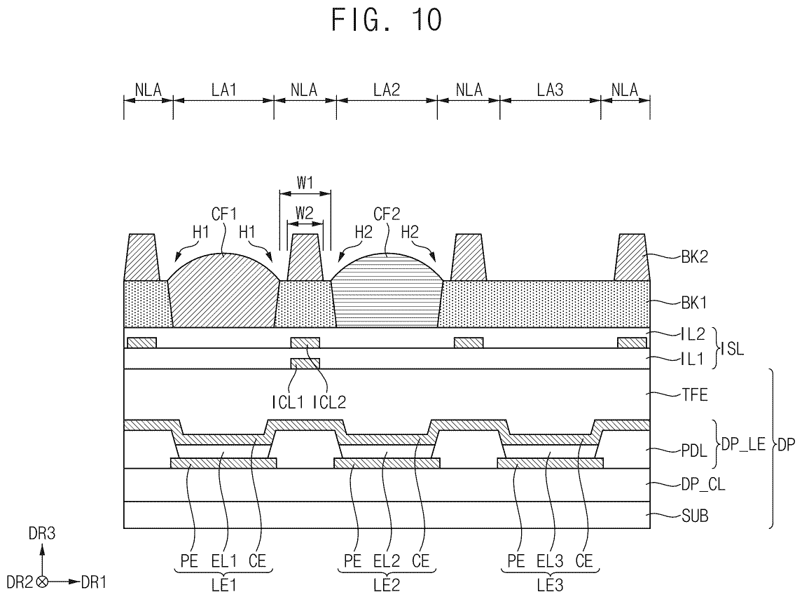

Referring to FIG. 10, the second bank BK2 may be formed in the non-light emitting area NLA, on the first bank BK1. The second bank BK2 may be formed to have the second width W2 in the first direction DR1. The second bank BK2 may selectively transmit the first light. For example, the second bank BK2 may be formed of a same material as the first color filter CF1.

As the second bank BK2 is formed, the first groove H1 may be formed between the first color filter CF1 and the second bank BK2, and the second groove H2 may be formed between the second color filter CF2 and the second bank BK2. Since there is no separate color filter in the third light emitting area LA3, no groove is provided at the third light emitting area LA3.

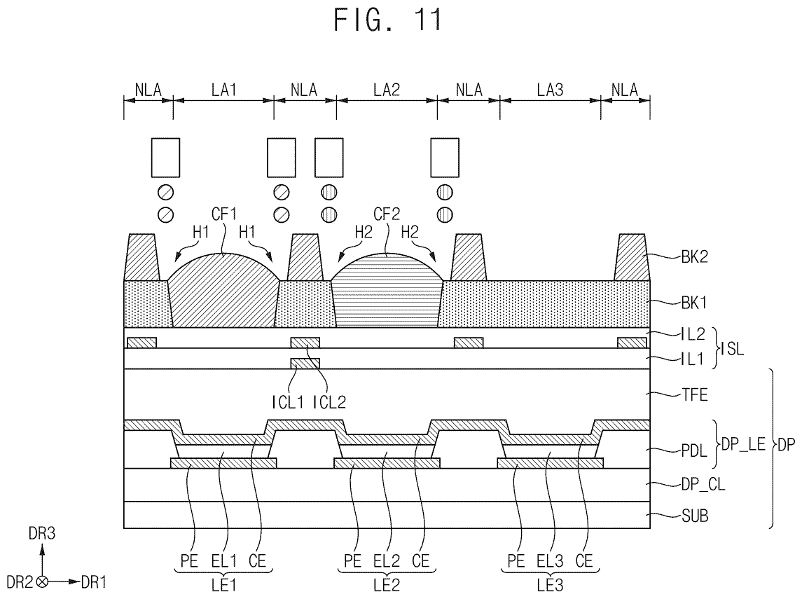

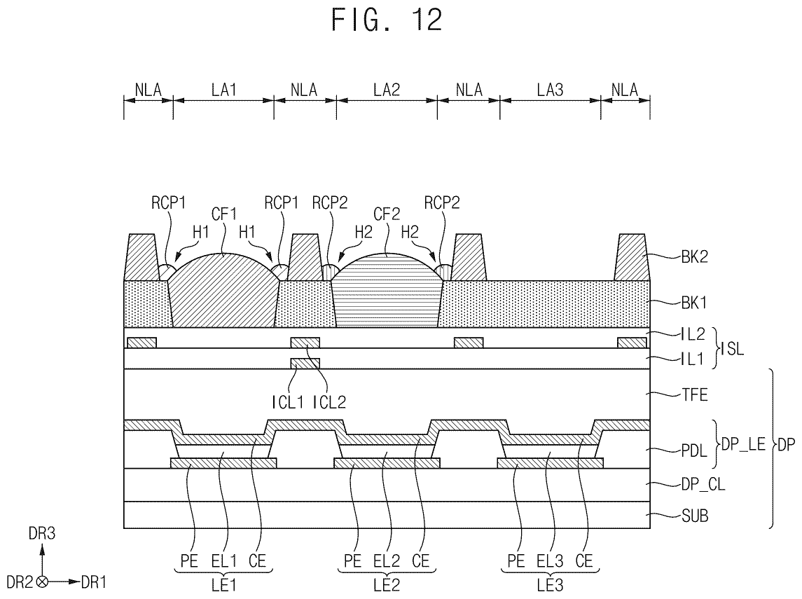

Referring to FIGS. 11 and 12, the first reflection control pattern RCP1 may be formed in the first groove H1, and the second reflection control pattern RCP2 may be formed in the second groove H2.

In an embodiment, the first and second reflection control patterns RCP1 and RCP2 may have a color which corrects a color of reflected light. For example, the first reflection control pattern RCP1 may be formed in the first groove H1 by dropping and curing ink of a color which corrects a color of reflected light in the first light emitting area LA1, and the second reflection control pattern RCP2 may be formed in the second groove H2 by dropping and curing ink of a color which corrects a color of reflected light in the second light emitting area LA2. For example, the first reflection control pattern RCP1 may be formed of ink of a color which corrects red, and the second reflection control pattern RCP2 may be formed of ink of a color which corrects green. For example, each of the first and second reflection control patterns RCP1 and RCP2 may be formed of ink of a primary color or a secondary color.

An order in which the first and second reflection control patterns RCP1 and RCP2 are formed may not be limited. For example, by forming the first reflection control pattern RCP1, irradiating external light to observe reflected light, and then forming the second reflection control pattern RCP2, irradiating external light to observe reflected light, color quality of reflected light may be adjusted. For another example, by forming the second reflection control pattern RCP2, irradiating external light to observe the reflected light, and then forming the first reflection control pattern RCP1, irradiating external light to observe the reflected light, color quality of reflected light may be adjusted.

Referring back to FIG. 8, the overcoating layer OCL may be formed on the first and second color filters CF1 and CF2, the first and second banks BK1 and BK2, and the first and second reflection control patterns RCP1 and RCP2 to form the color filter layer CFL. The window WM may be formed on the color filter layer CFL, and accordingly, the display device illustrated in FIG. 8 may be manufactured.

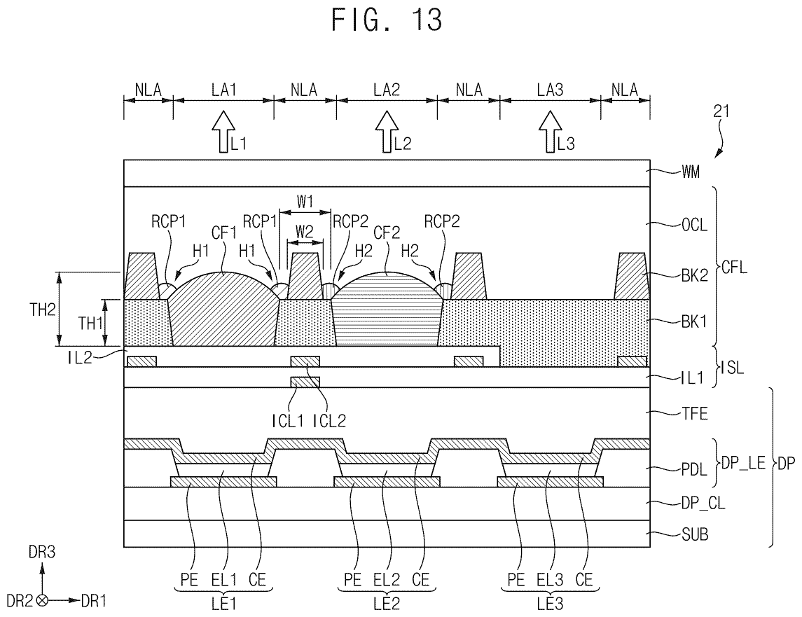

FIG. 13 is an enlarged cross-sectional view illustrating a display device 21 according to an embodiment of the present disclosure.

A display device 21 described with reference to FIG. 13 may be substantially same as or similar to the display device 20 described with reference to FIG. 12 except for the second input insulating layer IL2. Hereinafter, redundant descriptions will be omitted or simplified.

Referring to FIG. 13, the display device 21 may include a first light emitting area LA1, a second light emitting area LA2, a third light emitting area LA3, and a non-light emitting area NLA. Each of the first, second, and third light emitting areas LA1, LA2, and LA3 may be an area which emits light, and the non-light emitting area NLA may be an area which does not emit light.

In an embodiment, the first, second, and third light emitting areas LA1, LA2, and LA3 may emit light of different wavelength bands. The first light emitting area LA1 may emit first light L1, the second light emitting area LA2 may emit second light L2, and the third light emitting area LA3 may emit third light L3. For example, the first light L1 may be light of a red wavelength band, the second light L2 may be light of a green wavelength band, and the third light L3 may be light of a blue wavelength band, but the present disclosure is not limited thereto.

The display device 21 may include a display panel layer DP, an input sensing layer ISL, a color filter layer CFL, and a window WM.

The display panel layer DP may include a substrate SUB, a circuit layer DP_CL, an element layer DP_LE, and an encapsulation layer TFE. The input sensing layer ISL may be arranged on the display panel layer DP, and may include a first conductive layer ICL1, a first input insulating layer IL1, a second conductive layer ICL2, and a second input insulating layer IL2.

The first conductive layer ICL1 may be arranged in the non-light emitting area NLA, on the display panel layer DP, and may include a plurality of conductive patterns.

The first input insulating layer IL1 may be arranged on the first conductive layer ICL1, and may cover the first conductive layer ICL1.

The second conductive layer ICL2 may be arranged in the non-light emitting area NLA, on the first input insulating layer IL1, and may include a plurality of conductive patterns. Some of the plurality of conductive patterns of the second conductive layer ICL2 may be connected to the first conductive layer ICL1.

The second input insulating layer IL2 may be arranged on the first input insulating layer IL1 and the second conductive layer ICL2, and may cover at least a portion of each of the first input insulating layer IL1 and the second conductive layer ICL2.

In an embodiment, the second input insulating layer IL2 may be arranged in the first and second light emitting areas LA1 and LA2, and may not be arranged in the third light emitting area LA3. For example, the second input insulating layer IL2 may be arranged in the first and second light emitting areas LA1 and LA2 which emit light of a relatively long wavelength band, and may not be arranged in the third light emitting area LA3 which emits light of a relatively short wavelength band. In addition, the second input insulating layer IL2 may be arranged in at least a portion of the non-light emitting area NLA.

In an embodiment, the second input insulating layer IL2 may include scattering particles. The scattering particles may be dispersed in the second input insulating layer IL2. The scattering particles may scatter light reflected from lower components and advances to outside, thereby preventing a color band due to reflection from being visually recognized or reducing a degree of being visually recognized. In addition, as the scattering particles are not arranged in the third light emitting area LA3 which emits the third light L3, a decrease in light extraction efficiency of the display device 21 may be minimized.

Although FIG. 13 illustrates that the second input insulating layer IL2 is not arranged in the third light emitting area LA3, the present disclosure is not limited thereto, and in an embodiment, the second input insulating layer IL2 including the scattering particles may be further arranged in the third light emitting area LA3.

The color filter layer CFL may be arranged on the input sensing layer ISL, and may include a first bank BK1, a first color filter CF1, a second color filter CF2, a second bank BK2, a first reflection control pattern RCP1, a second reflection control pattern RCP2, and an overcoating layer OCL.

The first bank BK1 may be arranged in the third light emitting area LA3 and the non-light emitting area NLA, on the input sensing layer ISL. For example, when the second input insulating layer IL2 does not cover portions of each of the first input insulating layer IL1 and the second conductive layer ICL2, the first bank BK1 may cover the portions of each of the first input insulating layer IL1 and the second conductive layer ICL2.

The first bank BK1 may have a first width W1 in a first direction DR1, and may have a first thickness TH1 in a third direction DR3. The first width W1 may be a length in the first direction DR1 of the first bank BK1 arranged in the non-light emitting area NLA between the first and second light emitting areas LA1 and LA2, and the first thickness TH1 may be a length in the third direction DR3 of the first bank BK1 overlapping the second input insulating layer IL2 in a plan view.

In an embodiment, the first bank BK1 may transmit the third light L3, and may block light of a wavelength band different from that of the third light L3. The first bank BK1 may selectively transmit light of a relatively short wavelength band.

The first color filter CF1 may be arranged in the first light emitting area LA1, on the input sensing layer ISL, and the second color filter CF2 may be arranged in the second light emitting area LA2, on the input sensing layer ISL. The first color filter CF1 may selectively transmit the first light L1, and the second color filter CF2 may selectively transmit the second light L2. The first and second color filters CF1 and CF2 may have a second thickness TH2 in the third direction DR3. In an embodiment, the second thickness TH2 may be greater than the first thickness TH1.

The second bank BK2 may be arranged in the non-light emitting area NLA, on the first bank BK1. The second bank BK2 may transmit the first light L1, and may block light of a wavelength band different from that of the first light L1. For example, the second bank BK2 may include a same material as the first color filter CF1.

As the first bank BK1 which selectively transmits the third light L3 and the second bank BK2 which selectively transmits the first light L1 are stacked in the non-light emitting area NLA, reflection of external light due to lower components reflecting light may be reduced, and color mixing between the first, second, and third light emitting areas LA1, LA2, and LA3 may be prevented. In addition, reflection from a surface of the first bank BK1 may be reduced, thereby reducing reflection due to external light of the display device 21.

The second bank BK2 may have a second width W2 in the first direction DR1. In an embodiment, the second width W2 may be less than or equal to the first width W1.

As the second thickness TH2 may be greater than the first thickness TH1 and the second width W2 may be less than or equal to the first width W1, a first groove H1 may be defined between the first color filter CF1 and the second bank BK2, and a second groove H2 may be defined between the second color filter CF2 and the second bank BK2.

The first reflection control pattern RCP1 may be arranged in the first groove H1, and the second reflection control pattern RCP2 may be arranged in the second groove H2.

In an embodiment, the first and second reflection control patterns RCP1 and RCP2 may have a color which corrects a color of reflected light when external light is reflected from the display device 21. The first reflection control pattern RCP1 may include ink of a color which corrects a color of reflected light in the first light emitting area LA1, and the second reflection control pattern RCP2 may include ink of a color which corrects a color of reflected light in the second light emitting area LA2. For example, each of the first and second reflection control patterns RCP1 and RCP2 may include ink of a primary color or a secondary color.

When external light is reflected from the display device 21, the first and second reflection control patterns RCP1 and RCP2 may affect color quality of reflected light. In addition, a color reproducibility of the display device 21 may be improved by the first and second reflection control patterns RCP1 and RCP2.

The overcoating layer OCL may be arranged on the first and second color filters CF1 and CF2, the first and second banks BK1 and BK2, and the first and second reflection control patterns RCP1 and RCP2, and the window WM may be arranged on the color filter layer CFL.

The display device 10, 11, 20, and 21 according to embodiments of the present disclosure may be applied to various electronic devices. An electronic device according to an embodiment of the present disclosure may include the display device 10, 11, 20, and 21 described above, and may further include a module or device having additional functions in addition to the display device 10, 11, 20, and 21.

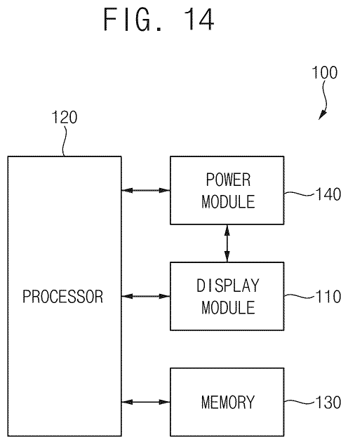

FIG. 14 is a block diagram illustrating an electronic device 100 according to an embodiment of the present disclosure.

Referring to FIG. 14, an electronic device 100 may include a display module 110, a processor 120, a memory 130, and a power module 140.

The processor 120 may include at least one of a central processing unit (CPU), an application processor (AP), a graphic processing unit (GPU), a communication processor (CP), an image signal processor (ISP), and a controller.

The memory 130 may store data information necessary for an operation of the processor 120 or the display module 110. When the processor 120 executes an application stored in the memory 130, an image data signal and/or an input control signal may be transmitted to the display module 110, and the display module 110 may process the received signal and output image information through a display screen.

The power module 140 may include a power supply module such as a power adapter, a battery device, or the like and a power conversion module which converts power supplied by the power supply module to generate power necessary for an operation of the electronic device 100.

At least one of the components of the electronic device 100 described above may be included in the display device according to an embodiment described above. In addition, some of individual modules functionally included in one module may be included in the display device, and others may be provided separately from the display device. For example, the display device may include the display module 110, and the processor 120, the memory 130, and the power module 140 may be provided in form of other devices in the electronic device 100 other than the display device.

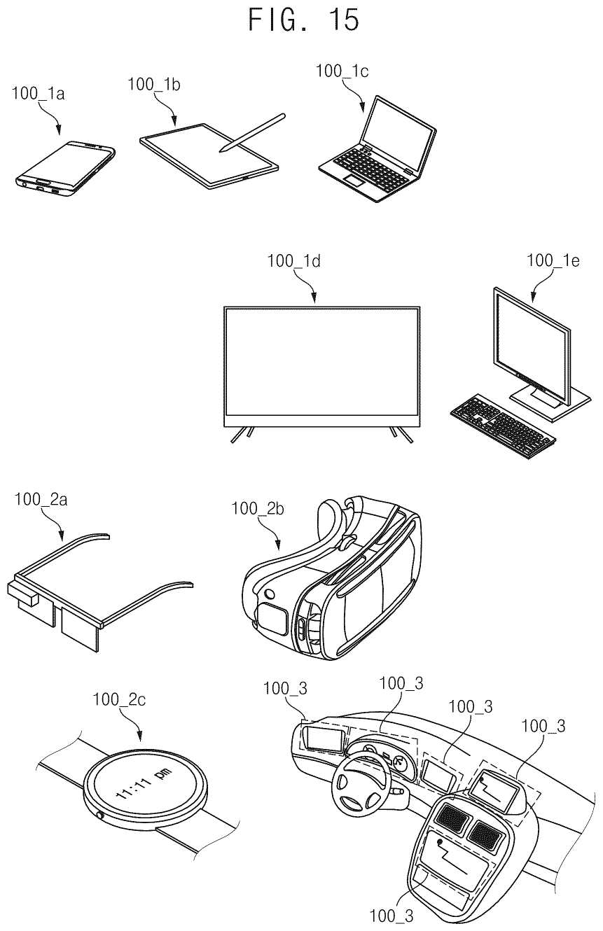

FIG. 15 is a schematic view illustrating electronic devices according to embodiments of the present disclosure.

Referring to FIG. 15, various electronic devices to which the display device according to an embodiment of the present disclosure is applied may include not only an image display electronic device, but also a wearable electronic device including a display module, a vehicle electronic device 100_3 including a display module, or the like. The image display electronic device may be a smartphone 100_1a, a tablet PC 100_1b, a laptop 100_1c, a television (TV) 100_1d, a desk monitor 100_1e, or the like. The wearable electronic device may be smart glasses 100_2a, a head mounted display 100_2b, a smart watch 100_2c, or the like. The vehicle electronic device 100_3 may be a center information display (CID) arranged on a dashboard and center fascia of a vehicle, a room mirror display, or the like.

In an embodiment, an electronic device includes a display device and a power module which supplies electrical power to the display device. The display device includes a display area including a light emitting area including a light emitting element and a color filter, and a non-light emitting area adjacent to the light emitting area, an encapsulation layer which is on the light emitting element, a bank structure which is in the non-light emitting area, on the encapsulation layer, a groove which is in the light emitting area and defined by the color filter together with the bank structure, and a reflection control pattern in the groove.

The present disclosure can be applied to various display devices and electronic devices. For example, the present disclosure is applicable to various display devices such as display devices for vehicles, ships and aircraft, portable communication devices, display devices for exhibition or information transmission, medical display devices, and the like.

The foregoing is illustrative of embodiments and is not to be construed as limiting thereof. Although a few embodiments have been described, those skilled in the art will readily appreciate that many modifications are possible in the embodiments without materially departing from the novel teachings and advantages of the present inventive concept. Accordingly, all such modifications are intended to be included within the scope of the present inventive concept as defined in the claims. Therefore, it is to be understood that the foregoing is illustrative of various embodiments and is not to be construed as limited to the specific embodiments disclosed, and that modifications to the disclosed embodiments, as well as other embodiments, are intended to be included within the scope of the appended claims.

What is claimed is:

1. An electronic device comprising:
a display device comprising:
a display area including:
a light emitting area including a light emitting element and a color filter, and
a non-light emitting area adjacent to the light emitting area;
an encapsulation layer on the light emitting element;
a bank structure which is in the non-light emitting area, on the encapsulation layer;
a groove which is in the light emitting area and defined by the color filter together with the bank structure; and
a reflection control pattern in the groove; and
a power module which supplies power to the display device.

2. The electronic device of claim 1, wherein
a light emitted from the light emitting area has a color, and
a color of the reflection control pattern is the same as the color of the light emitted from the light emitting area.

3. The electronic device of claim 1, wherein the bank structure includes:
a first bank having a first width in a width direction along the encapsulation layer; and
a second bank which is on the first bank and has a second width less than or equal to the first width in the width direction.

4. The electronic device of claim 3, wherein
the color filter faces the encapsulation layer along a thickness direction, and
a first thickness of the first bank in the thickness direction is less than a second thickness of the color filter in the thickness direction.

5. The electronic device of claim 3, wherein the groove is defined by surfaces of each of the color filter and the second bank.

6. The electronic device of claim 3, wherein the first bank and the second bank include different materials from each other.

7. The electronic device of claim 3, wherein the first bank includes a light blocking material.

8. The electronic device of claim 3, wherein the second bank includes a liquid-repellent material.

9. The electronic device of claim 3, wherein
the light emitting element is provided in plural including:
a first light emitting element which emits a first light;
a second light emitting element which emits a second light; and
a third light emitting element which emits a third light, and
the color filter is provided in plural including:
a first color filter overlapping the first light emitting element along a thickness direction;
a second color filter overlapping the second light emitting element in the thickness direction; and
a third color filter overlapping the third light emitting element in the thickness direction.

10. The electronic device of claim 9, wherein the groove is provided in plural including:
a first groove defined between the first color filter and the second bank, and
a second groove defined between the second color filter and the second bank.

11. The electronic device of claim 10, wherein the reflection control pattern is provided in plural including:
a first reflection control pattern in the first groove; and
a second reflection control pattern in the second groove.

12. The electronic device of claim 11, wherein
a color of the first reflection control pattern is the same as a color of the first light, and
a color of the second reflection control pattern is the same as a color of the second light.

13. The electronic device of claim 9, wherein
the first color filter transmits the first light,
the second color filter transmits the second light, and
the third color filter transmits the third light.

14. The electronic device of claim 9, wherein
the first light is light of a red wavelength band,
the second light is light of a green wavelength band, and
the third light is light of a blue wavelength band.

15. The electronic device of claim 9, wherein the first bank extends from the non-light emitting area to overlap the third light emitting element and defines the third color filter.

16. The electronic device of claim 15, wherein the third color filter and the first bank are respective portions of a same material layer.

17. The electronic device of claim 15, wherein the first color filter and the second bank include a same material.

18. The electronic device of claim 1, wherein the reflection control pattern is an inkjet pattern of a reflection material.

19. The electronic device of claim 1, wherein the reflection control pattern has a primary color including red or green, or a secondary color including cyan, magenta or yellow.

20. The electronic device of claim 1, wherein the color filter is an inkjet pattern of a color filter material.
